(19) United States
(12) Patent Application Publication
(10) Pub. No.: US 2009/0159915 A1
(43) Pub. Date: Jun. 25, 2009

(54) LED INSERT MODULE AND MULTI-LAYER LENS

(76) Inventor: Shaul Branchevsky, Mission Viejo, CA (US)

Correspondence Address: Kenton R. Mullins;Stout, Uxa, Buyan & Mullins, LLP, Suite 300, 4 Venture, Irvine, CA, 92618, US

(21) Appl. No.: 12/249,149

(22) Filed: Oct. 10, 2008

Related U.S. Application Data
(60) Provisional application No. 61/015,192, filed on Dec. 19, 2007.
(60) Provisional application No. 61/074,507, filed on Jun. 20, 2008.

(51) Int. Cl. H01L 33/00

(52) U.S. Cl. 257/98; 257/E33.061

(57) ABSTRACT

An LED insert module formed of a conducting carrier and a multi-layer lens is described. Layers of the lens are doped with phosphorescent material in order to control appearance of light produced by an LED die located in the insert module. Multiple modules may be embedded in a heat sink in order that the multiple modules may provide illumination to an area.

### CROSS-REFERENCE TO RELATED APPLICATIONS

This application claims the benefit of U.S. Provisional Application Nos. 61/015,192, filed Dec. 19, 2007 and of 61/074,507, filed Jun. 20, 2008, the entire contents of both which are hereby incorporated by reference.

### BACKGROUND OF THE INVENTION

1. Field of the Invention

The present invention relates generally to lighting applications and, more particularly, to light-emitting diodes used for illumination.

2. Description of Related Art

The need for lighting is ubiquitous in civilized society. Incandescent and fluorescent lighting devices are in common use, but present day environmental concerns create a need for lighting devices that consume significantly less energy than those traditional devices. Light-emitting diodes have been used to address this need.

### SUMMARY OF THE INVENTION

One illustrative embodiment of the present invention includes an illumination assembly comprising a carrier formed of electrically conductive material. At least one LED die may be secured to the carrier, the at least one LED die being configured to emit light. A lens, which may be secured to the carrier, may comprise a plurality of layers and may be disposed to direct the light to an illumination area. According to one particular embodiment of the present invention, the plurality of layers are formed of optically clear material doped with particles of phosphorescent material, the phosphorescent material being configured to absorb radiation and to emit light at a wavelength according to the phosphorescent material. At least one type of phosphorescent material may be employed including, for example, embodiments that use two and three types of phosphorescent material.

Another embodiment of the present invention may take a form of an LED assembly comprising at least one LED insert module. The at least one LED insert module may comprise a carrier formed of electrically conductive material and at least one LED die secured to the carrier, the at least one LED die being configured to emit light. The at least one LED insert module may further comprise a lens secured to the carrier, the lens comprising a plurality of layers disposed to direct the light to an illumination area. The assembly still further may comprise a heat sink configured to accept the at least one LED insert module and to dissipate heat generated within the at least one LED insert module.

While the apparatus has or will be described for the sake of grammatical fluidity with functional explanations, it is to be expressly understood that the claims, unless expressly formulated under 35 U.S.C. 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 U.S.C. 112 are to be accorded full statutory equivalents under 35 U.S.C. 112.

Any feature or combination of features described herein are included within the scope of the present invention provided that the features included in any such combination are not mutually inconsistent as will be apparent from the context, this specification, and the knowledge of one skilled in the art. For purposes of summarizing the present invention, certain aspects, advantages and novel features of the present invention are described herein. Of course, it is to be understood that not necessarily all such aspects, advantages or features will be embodied in any particular embodiment of the present invention. Additional advantages and aspects of the present invention are apparent in the following detailed description and claims that follow.

### BRIEF DESCRIPTION OF THE FIGURES

FIG. 1 is a cross-sectional view taken along a line 1-1′ of FIG. 2 illustrating an LED insert module that includes one LED die mounted directly to a carrier;

FIG. 2 is a top view of the LED insert module shown in FIG. 1;

FIG. 3 is a cross-sectional view taken along a line 3-3′ of FIG. 4 illustrating an LED insert module that includes two LED dies secured to bases mounted to the carrier;

FIG. 3A is a cross-sectional view taken along a line 3A-3A′ of FIG. 3B describing an LED insert module having two pins and including one LED die;

FIG. 3B is a top view of the LED insert module shown in FIG. 3A;

FIG. 4 is a top view of the LED insert module shown in FIG. 3;

FIG. 5 is a cross-sectional view taken along a line 5-5′ of FIG. 6 illustrating an LED insert module that includes two LED dies mounted directly to a carrier;

FIG. 6 is a top view of the LED insert module shown in FIG. 5;

FIG. 7 is a cross-sectional view taken along a line 7-7′ of FIG. 8 illustrating an LED insert module that includes one LED die having wire bonding connections to the LED die;

FIG. 8 is a top view of the LED insert module shown in FIG. 7;

FIG. 9 is a pictorial diagram illustrating operation of a multi-layer lens;

FIG. 10 is a cross-sectional view taken along a line 10-10′ of FIG. 11 illustrating an alternative implementation of the LED insert module shown in FIG. 1;

FIG. 11 is a top view of the LED insert module shown in FIG. 10;

FIG. 12 is a cross-sectional view taken along a line 12-12′ of FIG. 13 illustrating another alternative implementation of the LED insert module shown in FIG. 1;

FIG. 13 is a top view of the LED insert module shown in FIG. 12;

FIG. 14 is a cross-sectional view taken along a line 14-14′ of FIG. 15 showing an LED insert module disposed in a heat sink;

FIG. 15 is a top view of the LED insert module and heat sink shown in FIG. 14;

FIG. 16 is a pictorial diagram illustrating distribution of particles of phosphorescent material in layers of a multi-layer lens;

FIG. 17 is a pictorial diagram illustrating emission of light from a particle of phosphorescent material in response to light received from an LED;

FIG. 18 is a pictorial diagram illustrating light reflected from a particle of phosphorescent material;

FIG. 19 is a cross-sectional diagram illustrating a multi-layer lens with five layers;

FIG. 20 is a partial cross-sectional diagram of a multi-layer lens having eight layers and depicting exemplary light trajectories;

FIG. 21 is a pictorial diagram of an assembly comprising six LED insert modules mounted to a rectangular heat sink;

FIG. 22 is a pictorial diagram of an assembly comprising nine LED insert modules mounted to a circular heat sink;

FIG. 23 is cross-sectional view taken along a line 23-23′ of FIG. 24 illustrating a portion of an assembly comprising nine LED insert modules mounted to a dome-shaped heat sink;

FIG. 24 is a pictorial diagram of an assembly comprising nine LED insert modules mounted to a dome-shaped heat sink;

FIG. 25 is a pictorial diagram of an assembly comprising six LED insert modules mounted in a strip-type heat sink;

FIG. 26 is a cross-sectional view taken along a line 26-26′ of the assembly shown in FIG. 25;

FIG. 27 is a cross-sectional view of an LED insert module having layers disposed in a convex orientation;

FIG. 28 is a cross-sectional view of an LED insert module having layers disposed in a concave orientation;

FIG. 29 is a cross-sectional view taken along a line 29-29′ of FIG. 30 illustrating heat flow from an LED to a carrier and to a heat sink; and

FIG. 30 is a pictorial top view of a portion of an LED assembly further illustrating heat flow from the LED to the carrier and to the heat sink.

### DETAILED DESCRIPTION

Reference will now be made in detail to exemplary embodiments of the invention, examples of which are illustrated in the accompanying drawings. Wherever possible, the same or similar reference numbers are used in the drawings and the description to refer to the same or like parts. It should be noted that the drawings are in simplified form and are not to precise scale. In reference to the disclosure herein, for purposes of convenience and clarity only, directional terms, such as, top, bottom, left, right, up, down, over, above, below, beneath, rear, and front, are used with respect to the accompanying drawings. Such directional terms should not be construed to limit the scope of the invention in any manner.

Although the disclosure herein refers to certain illustrated embodiments, it is to be understood that these embodiments are presented by way of example and not by way of limitation. The intent of the following detailed description, although discussing exemplary embodiments, is to be construed to cover all modifications, alternatives, and equivalents of the embodiments as may fall within the spirit and scope of the invention as defined by the appended claims. It is to be understood and appreciated that the structures described herein do not cover a complete description for a process of manufacture of LED illumination devices. The present invention may be practiced in conjunction with various techniques that are conventionally used in the art, and only so much of the structural details are included herein as are necessary to provide an understanding of the present invention. The present invention has applicability in the field of illumination devices and processes in general. For illustrative purposes, however, the following description pertains to an LED insert module having a multi-layer lens.

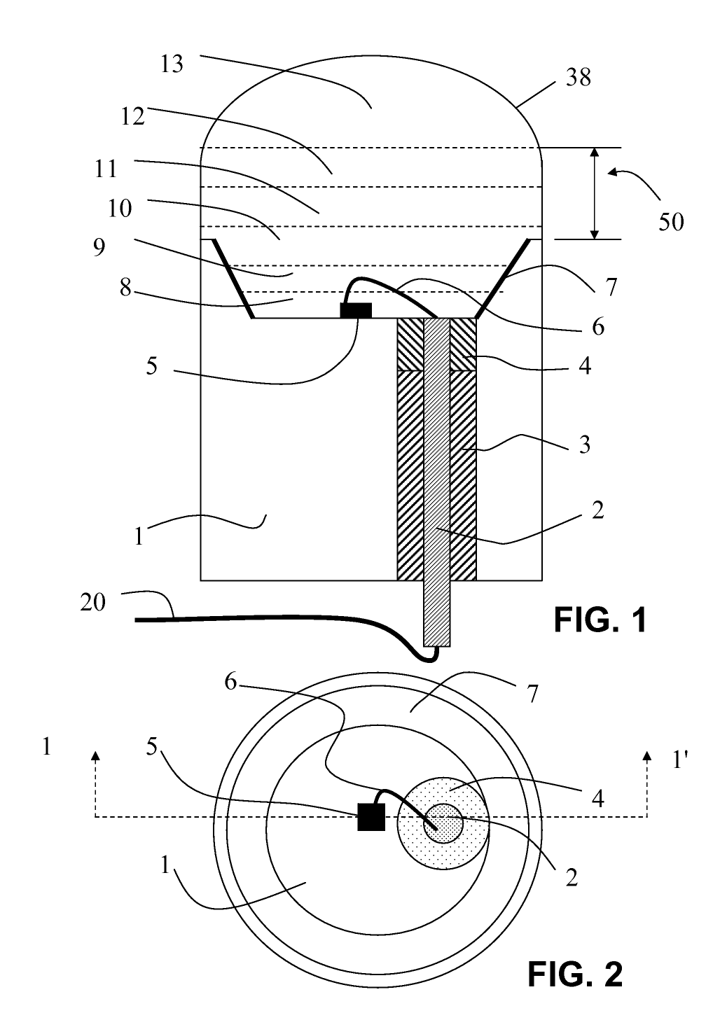

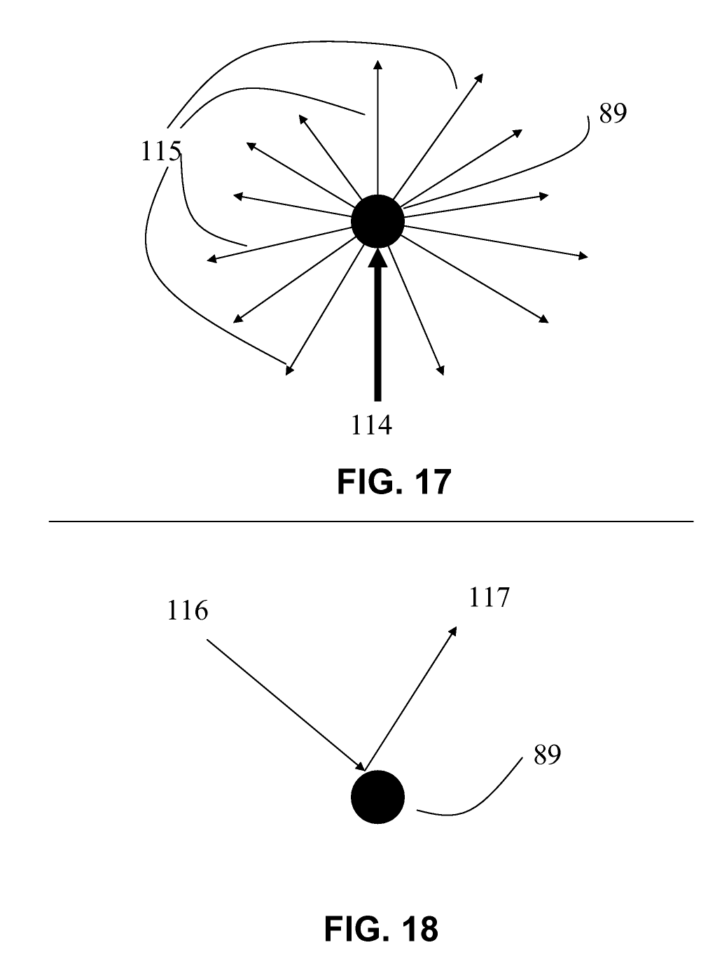

Referring more particularly to the drawings, FIGS. 1 and 2 are views of an LED insert module, which may be referred to as an illumination assembly, including one LED die mounted directly to a carrier. FIG. 1 is a cross-sectional view of the LED insert module taken along a line 1-1′ in FIG. 2, which is a top view of the LED insert module. FIGS. 1 and 2 show a carrier 1, an LED die 5 having an anode terminal and a cathode terminal (not shown), a reflector 7, a metal electrode, e.g., a pin 2, a sleeve 4, insulating material 3, bonding wire 6, cathode wire 20, and a multi-layer lens 38. In typical embodiments, the LED die 5 is configured to emit light that is reflected by the reflector 7. The reflected light, in addition to other light emitted by phosphors as described infra with reference to FIGS. 17, 18, and 20, passes through the multi-layer lens 38 to an illumination area (not shown). According to one particular embodiment, the carrier 1 may have a substantially cylindrical shape having an axis and a diameter of about ¼ inch and a height of about ¼ inch. Typical embodiments of the carrier 1 may be constructed of conductive material, e.g., metal, such copper, brass, aluminum, iron, and the like. The LED die 5 may be secured to the carrier 1 with solder or with conductive epoxy or adhesive in a manner that places the anode terminal of the LED die 5 in contact with the carrier 1. If solder is to be used, flux and solder may be applied to an area of the carrier 1 where the LED die 5 is to be attached, e.g., in a center part of the carrier 1 or in another desired location, and the solder reflowed to secure the LED die 5 to the carrier 1. If a conductive resin (e.g., epoxy) is to be used, a thin layer of conductive epoxy can be applied to the carrier 1 and the LED die 5 placed in contact with the conductive epoxy. The epoxy may then be cured according to recommendations of a supplier of the conductive epoxy. Alternatively, another type of conductive adhesive may be used to secure the LED die 5 to the carrier 1 using known methods.

The reflector 7, which, in the illustrated embodiment, is substantially circular with a substantially trapezoidal cross-section, is machined into the carrier 1 to an angle that may enhance reflection of light away from the LED 5 mounted to the carrier 1. In the embodiment illustrated in FIG. 1 the angle of the reflector 7 is about 37 degrees. The reflector 7 may be machined to a depth ranging from about 0.01 inch to 0.14 inch (e.g., 0.06 inch).

The reflector 7 and carrier 1 may be electroplated with nickel, solder, or similar materials.

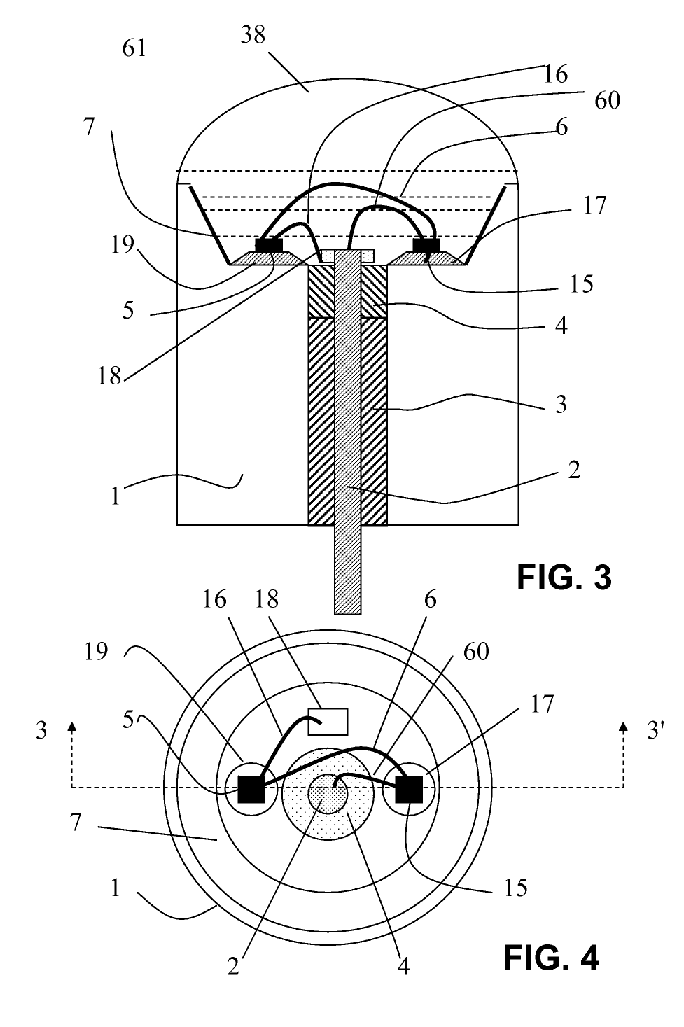

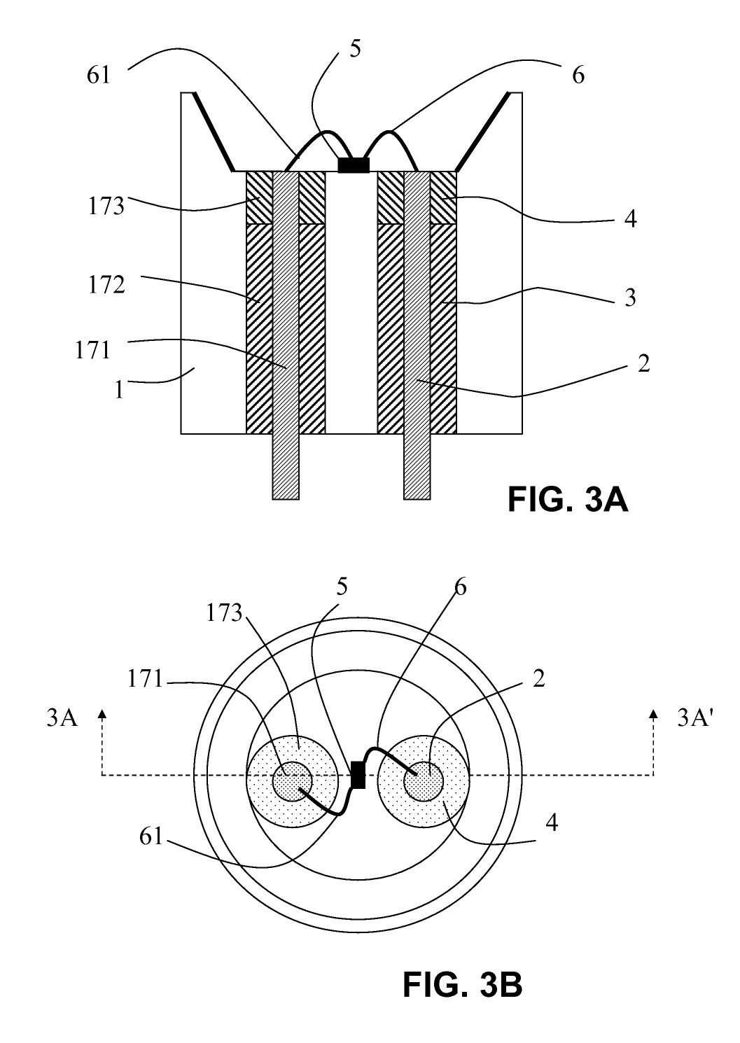

A hole substantially parallel to the axis may be formed in the carrier 1. The sleeve 4, which may comprise insulating material, may be disposed to surround a portion of the pin 2, and the pin 2 and the sleeve 4 may be passed through the hole. In the illustrated embodiment, a first end of the pin 2 and an end of the sleeve 4 are nominally flush with a surface of the carrier. In other embodiments (see, for example, FIGS. 3, 5, 7, 10, and 12) the first end of the pin 2 is not nominally flush with the surface of the carrier. An inner diameter of the hole may be slightly larger than an outer diameter of the sleeve 4, the inner diameter being about 0.078 inches in an exemplary embodiment. The pin 2, which may be formed of metal wire comprising, e.g., copper, brass, and the like, may be plated with nickel and gold, which gold plating may provide a wire-bonding capability between the LED die 5 and the pin 2. With the sleeve 4 and the accompanying pin 2 disposed in the hole, an available space between the pin 2 and the carrier 1 may be filled with insulating material 3 such as epoxy, resin, and the like. The insulating material 3 may be cured according to a recommendation of a supplier of the insulating material 3.

A cathode terminal (i.e., negative terminal) of the LED insert module may be formed by electrically connecting (e.g., soldering) the cathode wire 20 to a second end of the pin 2, the second end protruding slightly from the carrier 1 in the illustrated embodiment. When soldering, a temperature of approximately 200° C. may be employed. The configuration just described may be referred to as an LED insert module with the cathode wire 20 as its cathode and with the carrier 1 as its anode.

The bonding wire 6 may provide an electrical connection between the cathode terminal of the LED die 5 and the pin 2, the bonding wire 6 being formed of, for example, gold, aluminum, or any other metals normally used for wire bonding. According to one known method, the (e.g., 1 mil) bonding wire 6 may be connected by pre-heating the carrier 1, the pin 2, the insulating material 3, the sleeve 4, and the LED die 5 to approximately 125° C. and employing a wire bonding machine to place the bonding wire 6 in contact with the cathode terminal of the LED die 5 and the pin 2.

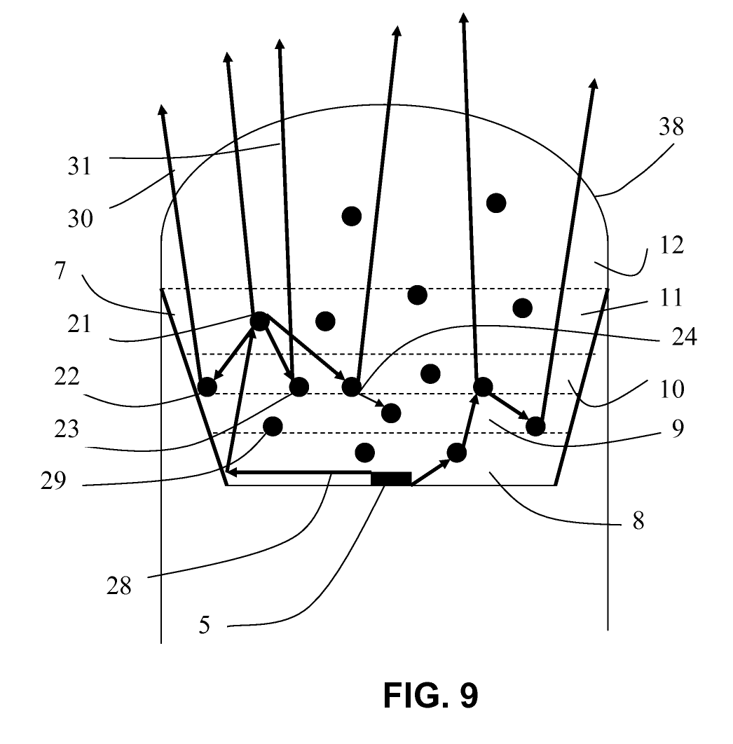

The multi-layer lens 38 may be formed of a plurality of layers of optically clear resin/polymer such as silicone, a room temperature vulcanizate (RTV), epoxy, or any other clear adhesive doped with particles of phosphorescent material, which particles may be referred to as phosphors in that which follows. Phosphors are not explicitly shown in FIGS. 1 and 2, but their operation is described more fully infra with reference to FIGS. 9, 16, 19, and 20. Generally, light from the LED die 5 may excite the phosphors, which then may emit light at a wavelength determined by the type of phosphorescent material composing the phosphors.

The multi-layer lens 38 illustrated in FIG. 1 comprises six layers. (Other embodiments may comprise other numbers of layers, which numbers may range, for example, from four to nine.) A first layer 8 disposed next to the LED die 5 may be clear or may have a small amount of phosphors suspended in material composing the first layer 8. A second layer 9 may have more phosphors suspended therein than does the first layer 8. Similarly, a third layer 10 may have more phosphors suspended therein than does the second layer 9. Again, a fourth layer 11 may have more phosphors suspended therein than does the third layer 10. A fifth layer 12 may have fewer phosphors suspended therein than does the fourth layer 11, and a sixth layer 13, which may be dome shaped, may have substantially no particles (or, alternatively, a very small number of particles) of phosphorescent material suspended therein.

The embodiment illustrated in FIGS. 1 and 2 includes a lens having an extension 50 having a height corresponding to a combined thickness of the fifth layer 12, the fourth layer 11, and a portion of the third layer 10 lying above an extent of the reflector 7 machined into the carrier 1. In another embodiment, the extension 50 may be eliminated, in which instance the number of layers in the multi-layer lens 38 of the embodiment illustrated in FIG. 1 is reduced to four.

According to an alternative description of the embodiment illustrated in FIGS. 1 and 2, it may be noted that the first layer is disposed nearer to the LED die 5 than is any other layer. The sixth layer 13 may be referred to as (in this instance) as a last layer. The remaining layers, i.e., the third layer 10 through the fifth layer 12, may be divided into two groups, a first group comprising, for example, the third layer 10 and the fourth layer 11, and a second group comprising the fifth layer 12. As already described, the fourth layer 11 may have more phosphors suspended therein than does the third layer 10. That is, each layer of the first group of layers comprises particles of phosphorescent material in a density that increases according to a distance from the LED die. Stated in yet another way, the third layer 10 through the fifth layer 12 may be divided into two other groups with the first group comprising, for example, the third layer 10. In that case, the second group may comprise the fourth layer 11 and the fifth layer 12. In the present example, the fifth layer 12 may have fewer particles of phosphorescent material suspended therein than has the fourth layer 11. That is, the layers in the second group comprise phosphors in a density that decreases according to a distance of each layer from the LED die. In other embodiments, the first and second groups of layers may contain more or fewer layers with the constituent layers in the first group (when the first group contains more than one layer) containing phosphors in a density that may increase with increasing distance from the LED die. Similarly, the constituent layers in the second group (when the second group contains more than one layer) may contain phosphors in a density that may decrease with increasing distance from the LED die.

Generally, a total amount of particles of phosphorescent material may be disposed within the plurality of layers forming the multi-layer lens 38 according to a total amount of phosphor required to create a desired amount of light to be emitted by the LED insert module. In some embodiments, the lens may contain no phosphors.

FIGS. 3 and 4 are views of an embodiment of another LED insert module including two LED dies mounted on bases that, in turn, are mounted to a carrier. FIG. 3 is a cross-sectional view of the LED insert module taken along a line 3-3′ in FIG. 4, which is a top view of the LED insert module. FIGS. 3 and 4 show a carrier 1, a first LED die 5, a second LED die 15, a first base 19, a second base 17, a reflector 7 as already described supra with reference to FIGS. 1 and 2, a pin 2, a sleeve 4, insulating material 3, a first bonding wire 6, a second bonding wire 60, a third bonding wire 16, a wire bonding plate 18, and a multi-layer lens 38. First and second LED dies 5 and 7 customarily have cathode (i.e., negative) and anode (i.e., positive) terminals. As with the illumination assembly described supra with reference to FIGS. 1 and 2, in typical embodiments of the LED insert module illustrated in FIGS. 3 and 4, first and second LED dies 5 and 15 are configured to emit light that is reflected by the reflector 7. The reflected light, in addition to other light emitted by phosphors as described infra with reference to FIGS. 17, 18, and 20, may pass through the multi-layer lens 38 to an illumination area (not shown).

The pin 2, the insulating material 3 and the spacer 4 may be disposed within the carrier 1 as described supra with reference to FIGS. 1 and 2. First base 19 and second base 17 may be formed of insulating material such as PCB and plastic. Other embodiments of first and second bases 19 and 17 may be formed of any conductive material including metal such as copper and brass. First and second bases 19 and 17 may be mechanically mounted to the carrier 1 using an adhesive material or solder. In turn, first LED die 5 may be mounted to first base 19 with adhesive material or solder in a manner that places neither the anode nor the cathode terminal of the LED die 5 in contact with the carrier 1. Second LED die 15 may similarly be mounted to second base 17. Further, the wire bonding plate 18 may be formed of conducting material and may be bonded to the carrier 1 with solder or a conductive adhesive. In a typical implementation, the second bonding wire 60 is connected between the pin 2 and a cathode terminal (not shown) of the second LED die 15. The first bonding wire 6 may be connected between an anode terminal of the second LED die 15 and a cathode terminal (not shown) of the first LED die 5. The third bonding wire 16 may be connected in a similar manner between an anode terminal of the first LED die 5 and the wire bonding plate 18, thereby effectively connecting the first LED die 5 and the second LED die 15 in series. It should be noted that, with the addition of a cathode wire 20 (FIG. 1) to FIG. 3 (the cathode wire is not shown in FIG. 3), the LED insert module of FIGS. 3 and 4 has an external appearance identical to that of the LED insert module of FIGS. 1 and 2, the only difference being that the LED insert module of FIGS. 3 and 4 includes two LED dies, not one. The embodiment of the multi-layer lens 38 as shown in FIG. 3 has five layers (not numbered in the figure).

It will be clear to one skilled in the art that the configuration of FIGS. 3 and 4 can be extended to include more than two LED dies in a single LED insert module. Further, the LED dies in the LED insert module may be connected either in series, in parallel, or in combinations of series and parallel.

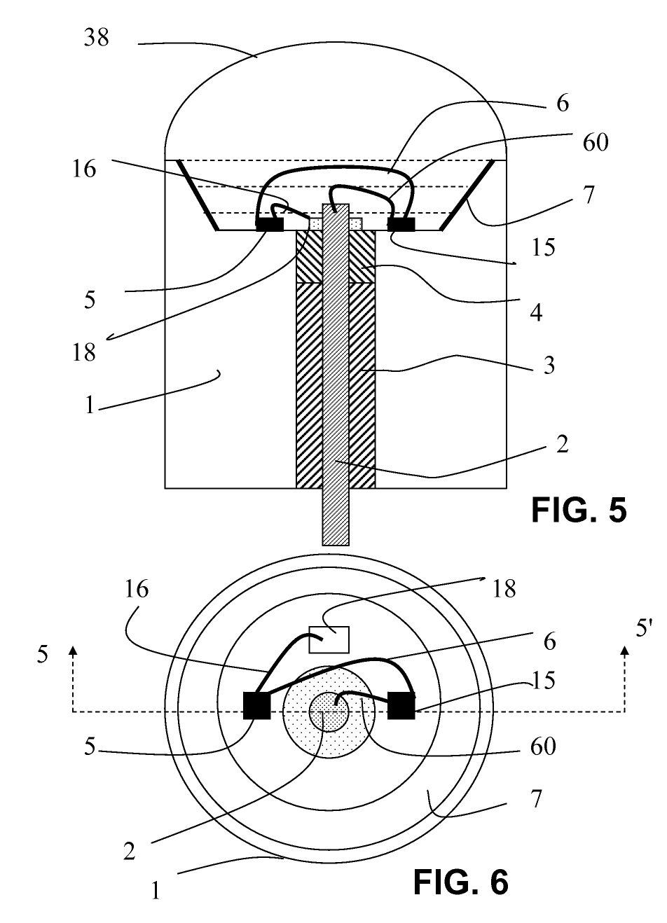

FIGS. 3A and 3B, where FIG. 3A is a cross-sectional view taken along a line 3A-3A′, illustrate another embodiment of an LED insert module closely related to the implementation shown in FIGS. 1 and 2. The embodiment of FIGS. 3A and 3B includes a first pin 2 and a second pin 171, a first sleeve 4 and a second sleeve 173, and first insulating material 3 and second insulating material 172. One of an anode and a cathode terminal on an LED die 5 in FIGS. 3A and 3B may be connected to the first pin 2, and the other of the anode and the cathode terminal on the LED die 5 may be connected to the second pin 171. Accordingly, the first pin 2 and the second pin 171 may form, respectively an anode and a cathode terminal (alternatively, a cathode and an anode terminal) of the LED insert module shown in FIGS. 3A and 3B. Other configurations, such as configurations comprising two or more LED dies connected in series and/or parallel will occur to one skilled in the art FIGS. 5 and 6 are pictorial diagrams (FIG. 5 is a cross-sectional view taken along a line 5-5′ of an LED insert module that combines aspects of the embodiment illustrated in FIGS. 1 and 2 and the embodiment illustrated in FIGS. 3 and 4. As with the embodiment shown in FIGS. 3 and 4, the present embodiment comprises two LED dies 5 and 15, but the LED dies 5 and 15 are not mounted on bases, but, rather, are mounted directly to a carrier 1 as shown in FIGS. 1 and 2. In other aspects, the embodiment of FIGS. 5 and 6 is similar to the embodiment of FIGS. 3 and 4 except that the embodiment of FIGS. 5 and 6 comprises a multi-layer lens 38 with four layers, not five.

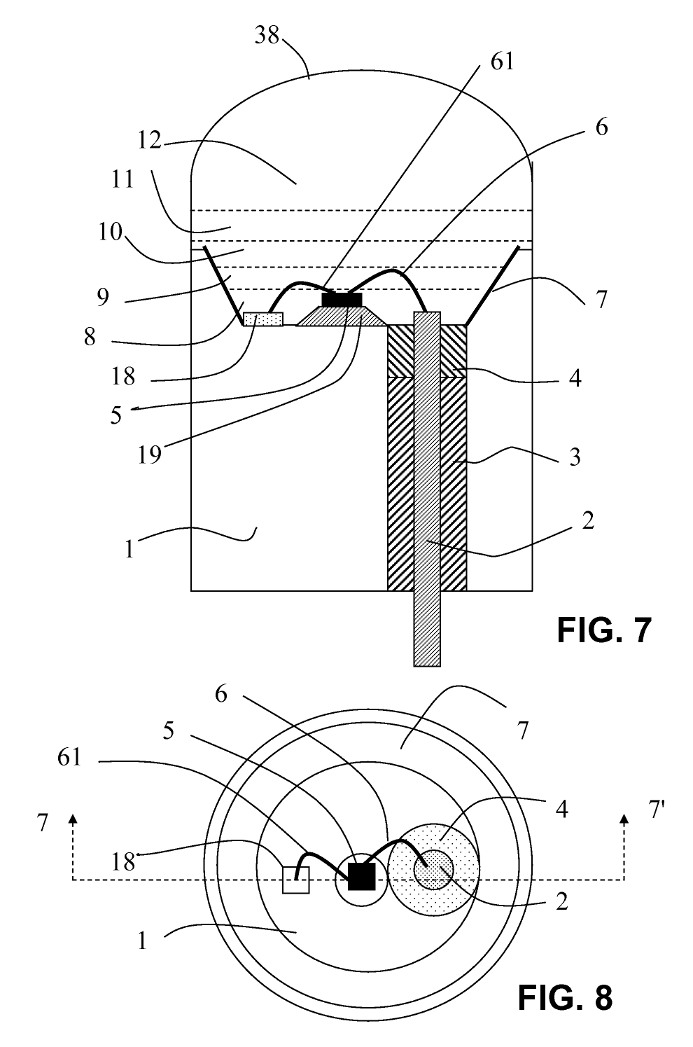

FIG. 7, which is a cross-sectional view taken along a line 7-7′ of FIG. 8 of yet another embodiment of an LED insert module, comprises a single LED die 5 mounted to a base 19 with a first bonding wire 6 that connects a pin 2 to a cathode terminal of the LED die 5. A second bonding wire 61 connects an anode terminal of the LED die 5 to a bonding plate 18 that is secured to a carrier 1 using, e.g., a conductive adhesive or solder. In other aspects, the embodiment of FIGS. 7 and 8 is similar to the embodiment of FIGS. 1 and 2 except that the present embodiment includes a multi-layer lens 38 having five layers 8, 9, 10, 11, and 12. According to one particular implementation of the embodiment of FIGS. 7 and 8, a first layer 8 of the multi-layer lens 38 has substantially no particles of phosphorescent material embedded therein. A second layer 9 has more particles of phosphorescent material embedded therein than does the first layer 8. Continuing, a third layer 10 has more particles of phosphorescent material embedded therein than does the second layer 9; a fourth layer 11 has more particles of phosphorescent material embedded therein than does the third layer 10; and a fifth layer 12, which may be dome shaped as illustrated, has substantially no particles of phosphorescent material embedded therein.

FIG. 9 is a pictorial diagram illustrating operation of a multi-layer lens. The figure shows a multi-layer lens 38 having five layers. In the diagram, large dots (e.g., 21, 22, 23, and 29) are intended to represent individual particles of phosphorescent material. Layers of the multi-layer lens 38 may be fabricated, according to one illustrative method, by mixing a first amount of substantially optically clear lens material (e.g., clear epoxy or resin) with a second amount of phosphorescent material. One way of describing the mixing may be to begin with a first amount (by weight, e.g., 50 g) of lens material mixed with a second amount (by weight, e.g., 5 g) of phosphorescent material and to define a reference ratio, r, as the second amount divided by the first amount (e.g., 0.1 or 10% in the present example). The mixture then may be formed into a layer that overlies a base (e.g., a previous layer or a carrier 1 as illustrated in FIG. 1) by, for example, injecting the mixture over the base and spinning or by smearing the mixture over the base. In FIG. 9, a first layer 8 of the multi-layer lens 38 may have about 1×n particles of phosphorescent material, which particles may be referred to as phosphors, embedded therein, where n represents a number of particles corresponding to, for example, a reference ratio, r as introduced supra. A second layer 9 may have about 2×n phosphors embedded therein, and a third layer 10 may have about 3×n phosphors embedded therein. A fourth layer 11 may have about 2×n phosphors embedded therein, and a fifth layer 12, which may be dome shaped may have about 1×n phosphors embedded therein. In the present example, a total number of phosphors may be about 1×n+2×n+3×n+2×n+1×n or about 9×n particles of phosphorescent material, which particles may be available to convert light generated by the LED die 5, at, say, a first wavelength, to desired light emitted by the multi-layer lens 38. The light emitted by the multi-layer lens 38, thereby, may comprise a spectrum of wavelengths according to materials chosen to implement the phosphors of each layer.

Arrows in the figure are intended to illustrate exemplary trajectories of light paths that result from light generated by an LED die 5. For example, light 28 generated by the LED die 5 may be reflected by reflector 7 and may impinge on a phosphor 21 in the fourth layer 11, which phosphor 21 may emit light at a wavelength according to the material comprising the phosphor 21. A portion of the light emitted by the phosphor 21 may strike other phosphors, for example, phosphors 22, 23, and 24. Other light emitted by the phosphor 21 may find its way upward and out of the multi-layer lens 38 and contribute to illuminating an illumination area (not shown). Additionally, light from phosphor 21 that strikes phosphor 24 may cause phosphor 24 to emit still more light, a portion of which may strike other phosphors, and another portion of which may be directed to the illumination area. Generally, the LED die 5 may serve as a primary source of light, but light that passes out of the lens may be generated mostly by phosphors that secondarily generate light according to materials of which phosphors are composed. Indeed, much of light useful for illumination may come, not from the LED die 5, but from phosphors located relatively far from the LED die 5.

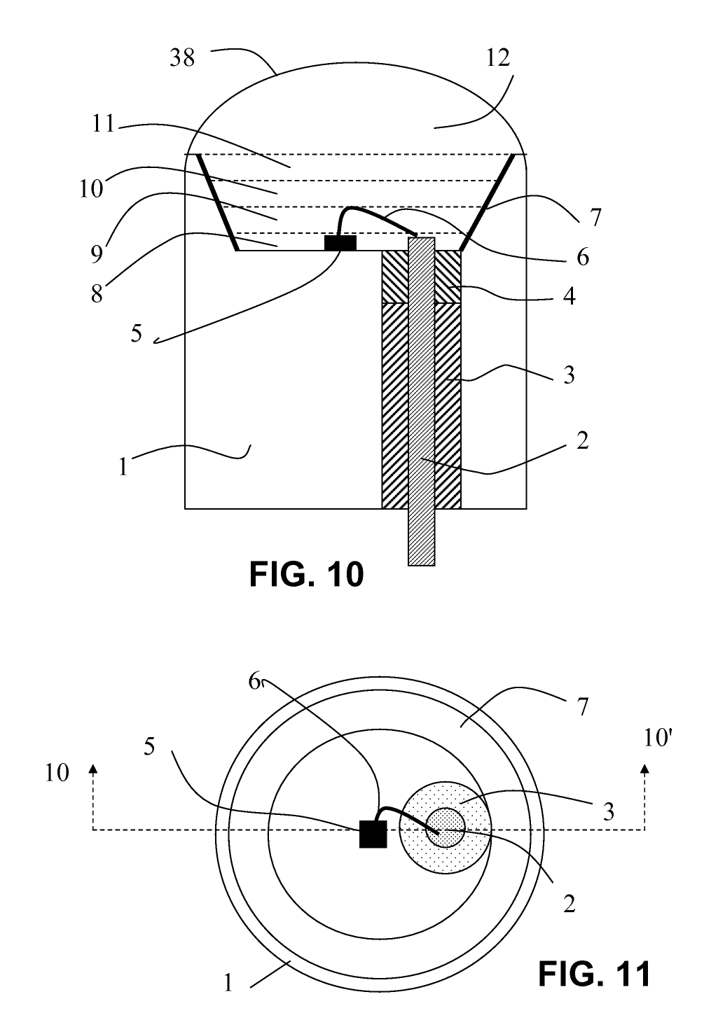

FIG. 10, which is a cross-sectional view taken along a line 10-10′ of an LED insert module, a top view of which is illustrated in FIG. 11, of an implementation of an LED insert module substantially similar to the embodiment shown in FIG. 1. The embodiment of FIGS. 10 and 11 differs from the embodiment of FIGS. 1 and 2, however, in that no extension 50 (FIG. 1) is present in the embodiment of FIGS. 10 and 11. Rather, a fifth layer 12, which is dome-shaped in the illustrated embodiment, commences at a far extend of a reflector 7. A first layer 8 in the multi-layer lens 38 illustrated in FIG. 10 may have substantially no particles of phosphorescent material suspended therein. A second layer 9 may have, for example about 2×n particles, a third layer 10 may have about 3×n particles, a fourth layer 11 may have about 2×n particles, and a fifth layer 12, which may be dome shaped, may have substantially no particles of phosphorescent material suspended therein. In this example, a total of about 2×n+3×n+2×n or about 7×n particles are available for converting light generated by the LED die 5 at an LED wavelength to emitted light having a spectrum of different wavelengths.

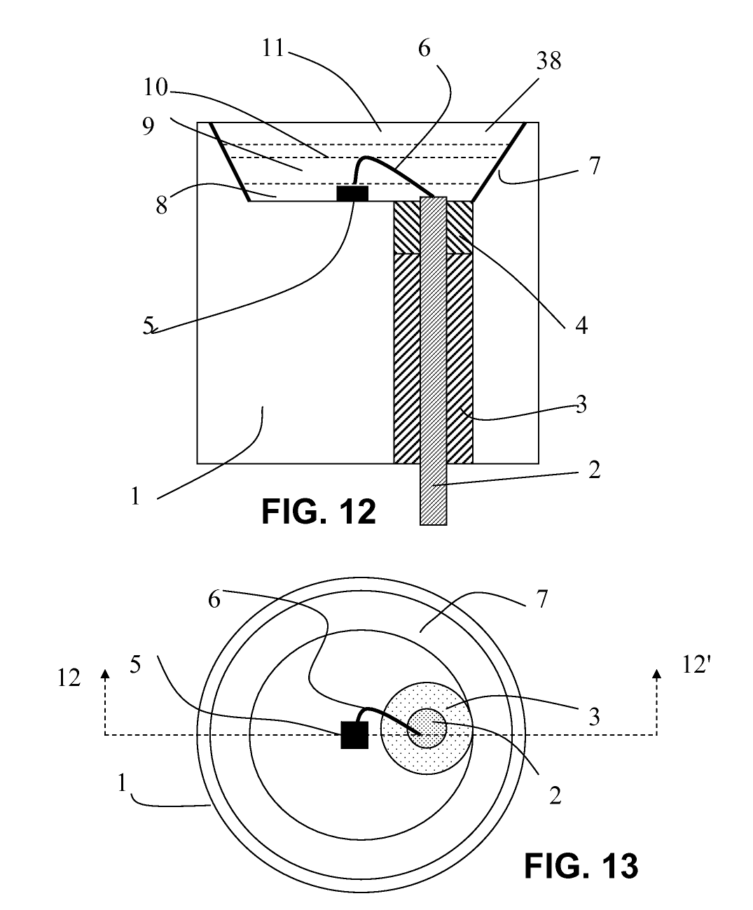

FIGS. 12 and 13 illustrate yet another embodiment of an LED insert module. FIG. 12 is a cross-sectional view of the LED insert module taken along a line 12-12′ in FIG. 13, which is a top view of the LED insert module. The implementation of FIG. 12 is substantially similar to the implementation shown in FIG. 10 with the fifth layer 12 (FIG. 10) of the multi-layer lens 38 (FIG. 10) removed.

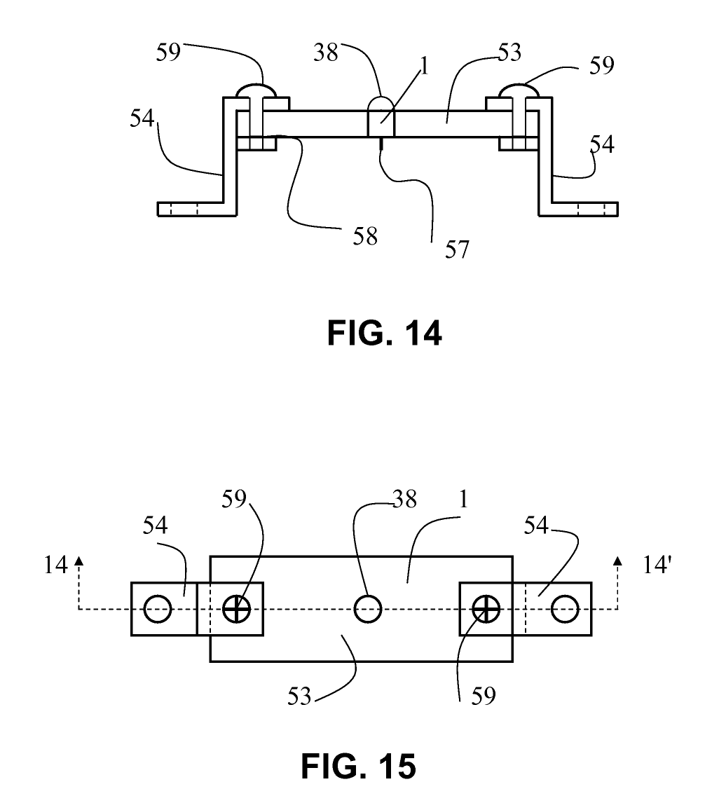

FIGS. 14 and 15 depict an LED insert module mounted in a heat sink. FIG. 15 is a top view of the LED insert module mounted in the heat sink, and FIG. 14 is a cross-sectional view taken along a line 14-14′ of FIG. 15. The LED insert module, an illustrative example of which is shown in FIGS. 1 and 2, may comprise a nominally cylindrical carrier 1 as already described. With a hole mated to the carrier 1 formed in a heat sink 53, the carrier 1 of the LED insert module may fit snugly in the heat sink 53, thereby providing for dissipation in the heat sink 53 of heat generated by the LED insert module. The illustrated embodiment further shows heat sink holders 54, which may be formed, for example, of plastic, and screws 59 that facilitate attachment of the heat sink 53 to the heat sink holders 54 in a known manner.

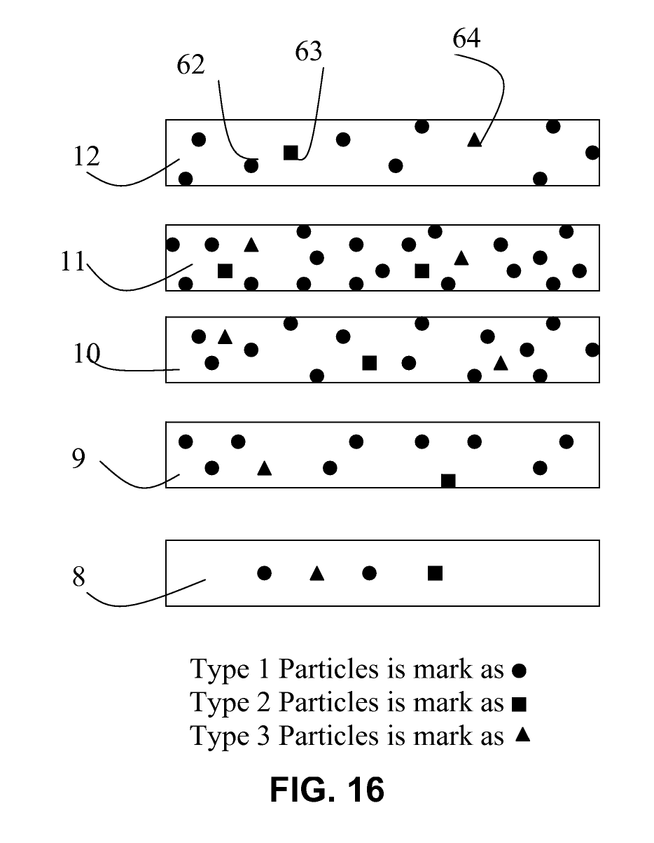

FIG. 16 is a pictorial diagram illustrating one particular distribution of particles of phosphorescent material in layers of a multi-layer lens. The figure may be considered a breakout of a portion of the multi-layer lens 38 shown in FIG. 1 where only layers 8, 9, 10, 11, and 12 are shown. The figure illustrates that various types of particles of phosphorescent material, which may be referred to as phosphors, may appear in each layer of the multi-layer lens 38. For example, a first type 62 of phosphor is represented as a dark circle in the figure. Similarly, a second type 63 and a third type 64 of phosphor are represented, respectively, by dark squares and dark triangles. Various distributions and densities of phosphors may be employed in various implementations of the multi-layer lens 38, and a number of types of phosphors greater or less than three may be employed. In the particular example illustrated in FIG. 16, layer 8 is nearest the LED die 5 (FIG. 1) and is doped with a relatively small amount of particles having first, second, and third types. Layer 9 contains a somewhat greater density of particles of phosphorescent material than does layer 8. Layers 10 and 11 are implemented with a density of phosphors that increases with distance from the LED die 5 (FIG. 1), and layer 12 has a smaller density of phosphors than does layer 11. In general, each layer can include zero to one hundred percent of a reference number of particles depending upon design details and illumination requirements. The total number and types of particles employed may be chosen to change specific wavelengths of light to light at another wavelength. Various combinations of wavelengths of light may thereby be created in order to illuminate an illumination area with light that is pleasing or appropriate to a specific application.

FIG. 17 is a pictorial diagram illustrating emission of light from a particle of phosphorescent material in response to light received from an LED. A particular particle of phosphorescent material or phosphor 89 shown in FIG. 17 may receive light 114 from an LED, the received light 114 having a wavelength according to the LED. The phosphor 89 may absorb energy from the received light 114 and may emit light 115 omni directionally, the emitted light 115 having a wavelength according to the phosphor 89.

FIG. 18 is a pictorial diagram illustrating another aspect of light reflected from a particle of phosphorescent. In particular, the phosphor 89 may receive light 116 from any source. Examples of sources are an LED, a reflector that reflects light received from a source, and another particle of phosphorescent material. As such, the received light 116 may have a wavelength according to the source that generated the received light 116. The phosphor 89 may receive energy from the received light 116 and may emit light 117 having a wavelength according to the phosphor 89.

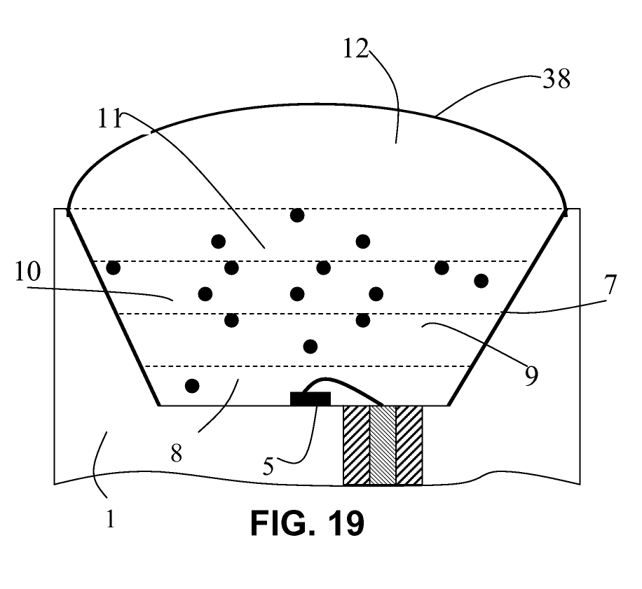

FIG. 19 is a cross-sectional diagram illustrating an embodiment of a multi-layer lens 38 with five layers. The illustrated embodiment may comprise a first layer 8 having, for example, 0.5×n particles of phosphorescent material, where n is a number of particles of phosphorescent material (i.e., phosphors) corresponding to a reference ratio, r, as described supra with reference to FIG. 9. In the illustrated example, a second layer 9 may contain 1×n particles of phosphorescent material. Similarly, a third layer 10 may contain 2×n, a fourth layer 11 may contain 3×n, and a fourth layer 12 may comprise a dome containing substantially no particles of phosphorescent material. Of course, this is only one example, and other embodiments may comprise a multi-layer lens wherein each layer comprises a number of particles corresponding to a reference ratio that may range up to 100% in some cases. It should be emphasized that not only the number, n, of phosphorescent particles can be varied, but that various types of phosphorescent material may chosen to implement the layers of the multi-layer lens according to a desired illumination characteristic For example, if white illuminating light is required, then a particular type of phosphors may be chosen with blue LED light; if red illuminating light is desired, then, perhaps, no phosphors at all may be used, assuming that a red LED is employed.

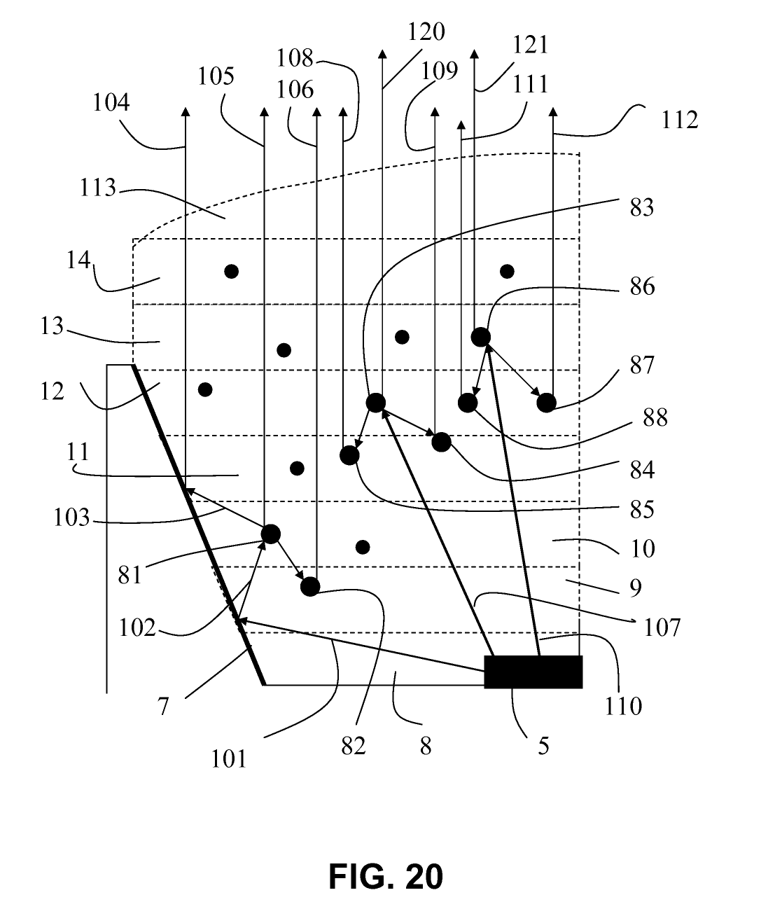

FIG. 20 is a partial cross-sectional diagram of another multi-layer lens having eight (i.e., first through eight) layers and depicting exemplary light trajectories. In the illustrated embodiment, a first layer 8 of the multi-layer lens is doped with substantially no particles of phosphorescent material. Second layer 9, third layer 10, fourth layer 11, and fifth layer 12 may be doped with increasing numbers of particles, the respective second through fifth layers comprising about 1×n, 2×n, 3×n, 4×n particles where n is a number derived from a reference ratio as already described. Continuing, ninth, tenth, eleventh and twelfth layers 13, 14, and 113 may be doped with decreasing numbers of particles, the respective ninth through twelfth layers 13, 14, and 113 including about 3×n, 2×n, and 0×n particles. Twelfth layer 113 is dome shaped and contains substantially no particles of phosphorescent material.

In one exemplary operating scenario, an LED die 5 may generate light, a portion 101 of which may strike a reflector 7 generating a light portion 102 that strikes a phosphor 81. Light from phosphor 81 may strike another phosphor 82, which may respond by emitting light, a portion 106 of which is directed out of the lens to an illumination area (not shown). Another portion 103 of the light emitted by the phosphor 81 may strike the reflector 7 resulting in light 104 that is reflected out of the lens to the illumination area (not shown). Similarly, another portion 110 of light generated by the LED die 5 may impinge on another phosphor 86, which may respond by emitting light, a portion of which strikes yet another phosphor 87 and still another phosphor 88. Phosphors 87 and 88 may, in turn, respond by generating light, portions 112 and 121 of which may find their way out of the lens to the illumination area.

It should be clear that light emitted by the LED die 5 may result in chain reactions of light generation at various wavelengths from phosphors of varying types and densities in various layers of the multi-layer lens. The multi-layer nature of the lens, along with the variable densities of phosphors in each layer, may enhance an ability of an LED to produce light useful for a variety of illumination applications.

The various embodiments of LED insert modules described supra with reference to FIGS. 1-8 and 10-13 may be readily adapted to be installed in a heat sink. The heat sink may take on several shapes according to requirements of illumination applications. Several examples follow.

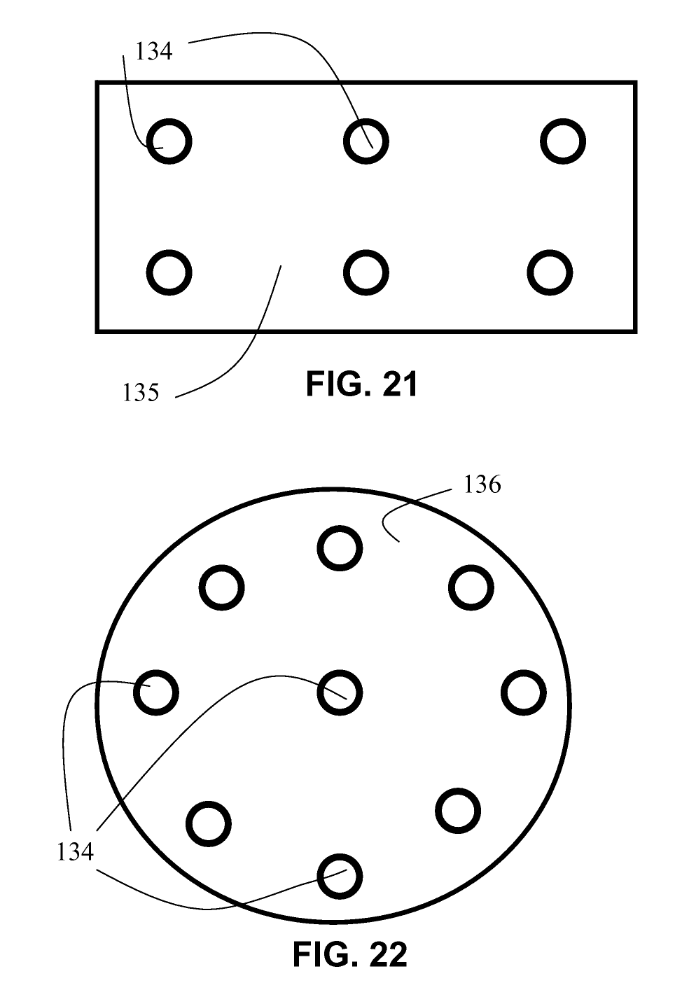

As a first example, FIG. 21 is a pictorial diagram an assembly comprising six LED insert modules mounted to a rectangular heat sink. The illustrated heat sink 135 may comprise a rectangular bar having respective dimensions of length, width and depth of about 4, 2, and ¼ inches according to one exemplary embodiment. The heat sink 135 may have a plurality of holes 134 (e.g., six holes) drilled therein that accommodate a plurality of LED insert modules that may be pressure-fit into the holes. In another configuration, FIG. 22 shows a plurality (e.g., nine) holes 134 that may accommodate a plurality of LED insert modules in a disk-shaped heat sink 136. Again, the plurality of LED modules may be pressure-fit into the plurality of holes.

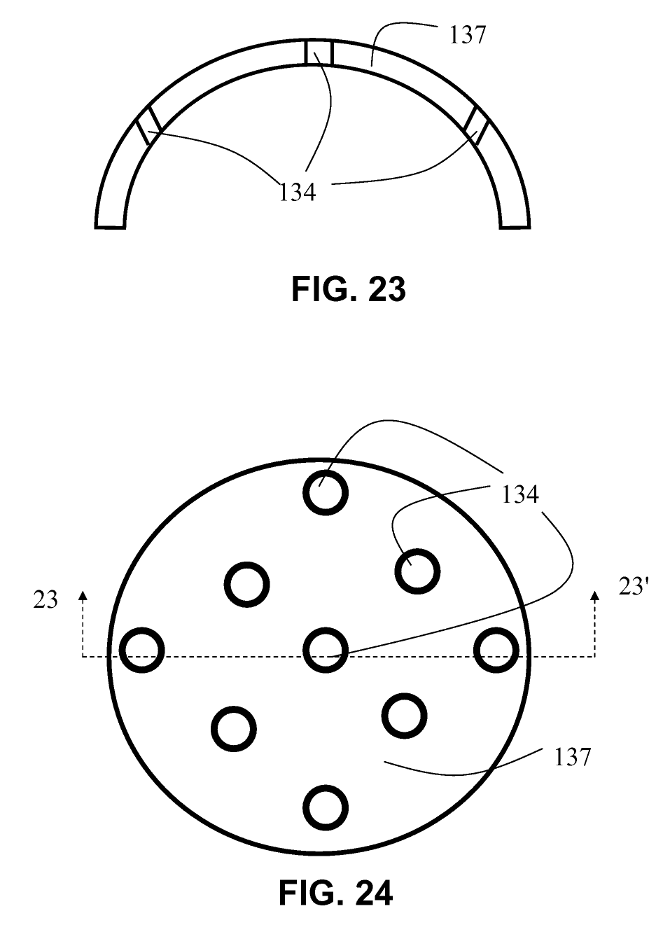

As another example, FIG. 23 is a cross-sectional view taken along a line 23-23′ of FIG. 24 illustrating a portion of an assembly that may accept a plurality (e.g., nine) of LED insert modules mounted to a dome-shaped heat sink 137.

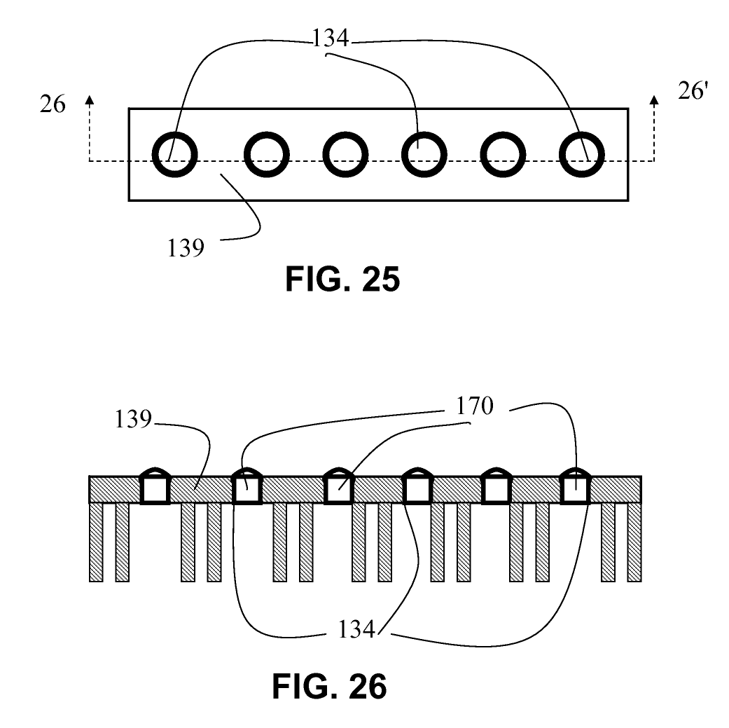

Illustrating yet another heat sink configuration, an implementation shown in FIGS. 25 and 26 shows a plurality (e.g., six) of LED insert modules 170 mounted to a bar- or strip-shaped heat sink 139. FIG. 26, which is a cross-sectional view taken along a line 26-26′ of the assembly shown in FIG. 25, illustrates cross-sections of the plurality of LED insert modules 170 that may be pressure-fit into a plurality of holes 134 in the heat sink 139.

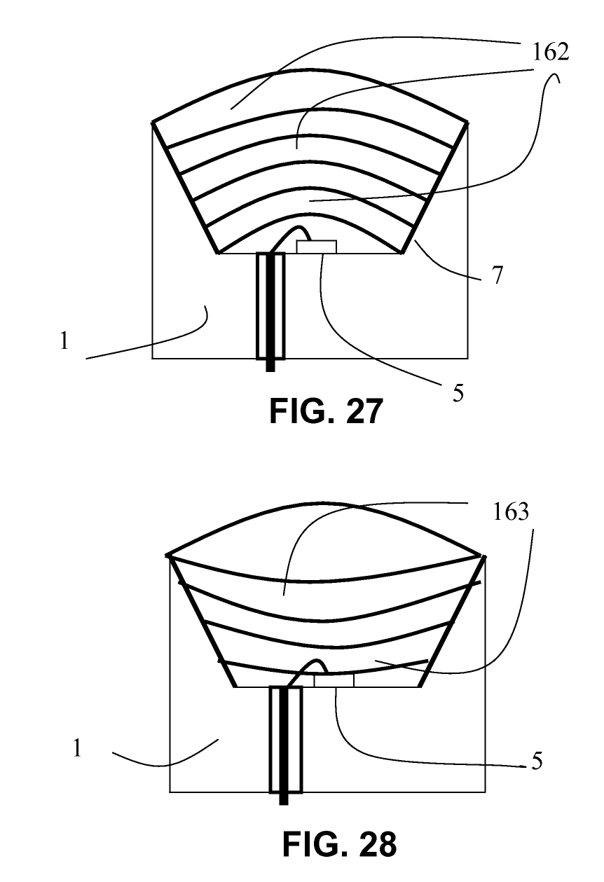

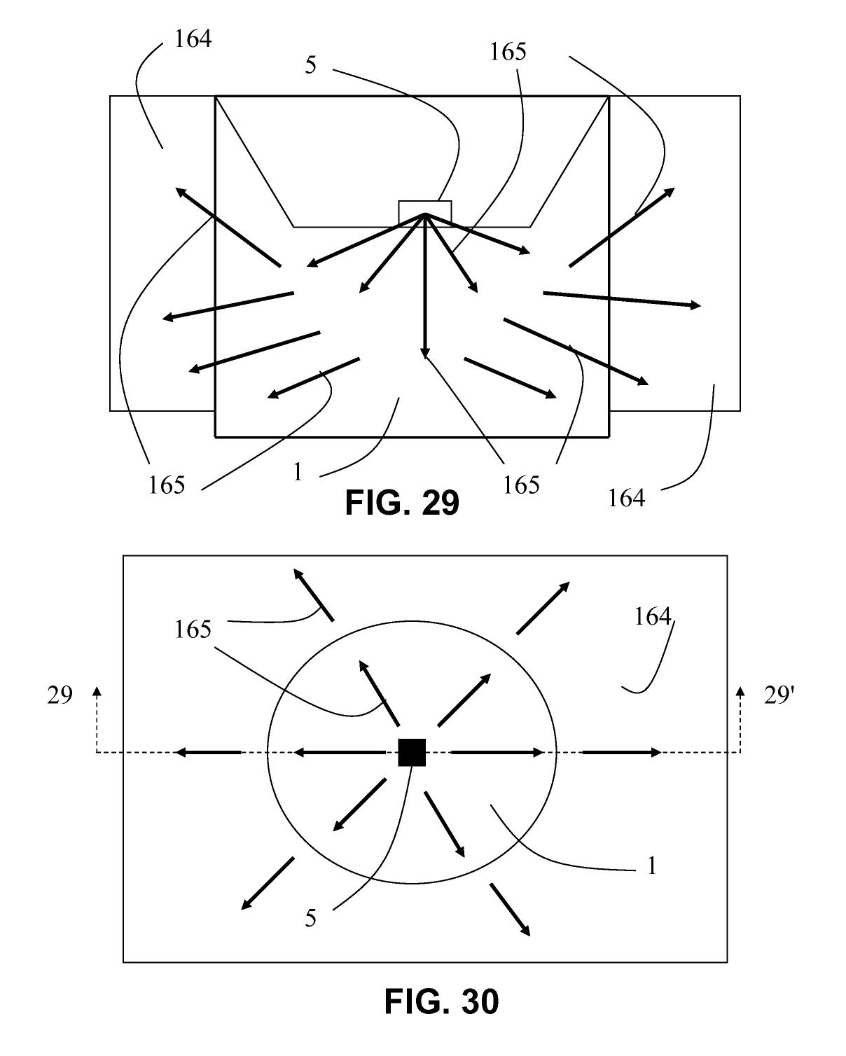

Many of the embodiments of multi-layer lenses illustrated supra have comprised a plurality of lens layers having a nominal shape of a flat disc. FIG. 27 illustrates another embodiment of an LED insert module with a multi-layer lens comprising a plurality of convex-shaped layers 162. In contrast, FIG. 28 illustrates yet another embodiment comprising a plurality concave layers 163 in a multi-layer lens. An overall dome shape to the multi-layer lens of the embodiment shown in FIG. 28 may be achieved by shaping a layer farthest from the LED 5 to have a dome shape mated to a concave shaped lower layer of the multi-layer lens

In view of the foregoing, it will be understood by those skilled in the art that the methods of the present invention can facilitate formation of LED-based illumination devices. The above-described embodiments have been provided by way of example, and the present invention is not limited to these examples. Multiple variations and modification to the disclosed embodiments will occur, to the extent not mutually exclusive, to those skilled in the art upon consideration of the foregoing description. Additionally, other combinations, omissions, substitutions and modifications will be apparent to the skilled artisan in view of the disclosure herein. Accordingly, the present invention is not intended to be limited by the disclosed embodiments, but is to be defined by reference to the appended claims.

What is claimed is:

1. An illumination assembly comprising:
a carrier formed of electrically conductive material;
at least one LED die secured to the carrier, the at least one LED die being configured to emit light; and
a lens comprising a plurality of layers formed of optically clear material, the lens being secured to the carrier, the lens further being disposed to direct the light to an illumination area.

2. The illumination assembly as set forth in claim 1, wherein the plurality of layers are doped with particles of phosphorescent material, the phosphorescent material being configured to absorb radiation and to emit light at a wavelength according to the phosphorescent material.

3. The illumination assembly as set forth in claim 2, wherein the particles of phosphorescent material comprise at least one type of phosphorescent material.

4. The illumination assembly as set forth in claim 3, wherein the at least one type of phosphorescent material comprises one of one, two, and three types of phosphorescent material.

5. The illumination assembly as set forth in claim 2, wherein the plurality of layers comprise at least four layers.

6. The illumination assembly as set forth in claim 5, wherein:
the at least four layers comprise a first layer, a last layer and a subplurality of layers disposed between the first layer and the last layer, the subplurality of layers comprising a first group of layers and a second group of layers;
the first layer is disposed nearer to the at least one LED die than is any other layer;
the first group of layers is disposed nearer to the at least one LED die than is the second group of layers;
the first layer is doped with substantially no particles of phosphorescent material;
the last layer is doped with substantially no particles of phosphorescent material;
each layer in the first group of layers comprises particles of phosphorescent material in a density that increases according to a distance of the layer from the at least one LED die; and
each layer in the second group comprises particles of phosphorescent material in a density that decreases according to the distance of the layer from the at least one LED die.

7. The illumination assembly as set forth in claim 6, wherein:
the particles of phosphorescent material in the plurality of layers are configured to receive light from the at least one LED die; and
the particles of phosphorescent material in one of the plurality of layers are further configured to receive light from phosphorescent material in the plurality of layers.

8. The illumination assembly as set forth in claim 5, wherein:
the plurality of layers comprise six layers;
a first layer is disposed nearest to the at least one LED die and is doped with substantially no particles of phosphorescent material;
a second layer is disposed next to the first layer and is doped with a greater number of particles of phosphorescent material than is the first layer;
a third layer is disposed next to the second layer and is doped with a greater number of particles of phosphorescent material than is the second layer;
a fourth layer is disposed next to the third layer and is doped with a greater number of particles of phosphorescent material than is the third layer;
a fifth layer is disposed next to the fourth layer and is doped with a lesser number of particles of phosphorescent material than is the fourth layer; and
a sixth layer is disposed farthest from the at least one LED die and is doped with substantially no particles of phosphorescent material.

9. The illumination assembly as set forth in claim 5, wherein:
the plurality of layers comprises five layers;
the first layer is disposed nearest to the at least one LED die and is doped with a reference number of particles of phosphorescent material;
the second layer is disposed next to the first layer and is doped with about twice the reference number of particles of phosphorescent material;
the third layer is disposed next to the second layer and is doped with about three times the reference number of particles of phosphorescent material;
the fifth layer is disposed next to the fourth layer and is doped with about twice the reference number of particles of phosphorescent material; and
the sixth layer is disposed farthest from the at least one LED die and is doped with substantially the reference number of particles of phosphorescent material.

10. An LED insert module comprising:
a carrier formed of electrically conductive material;
at least one LED die secured to the carrier, the at least one LED die being configured to emit light; and
a lens comprising a plurality of layers, the layers being formed of optically clear material doped with particles of phosphorescent material, the phosphorescent material being configured to absorb radiation and to emit light at a wavelength according to the phosphorescent material, the lens being secured to the carrier and disposed to direct to an illumination area light emitted by the at least one LED die and light emitted by the phosphorescent material.

11. The LED insert module as set forth in claim 10, wherein the carrier comprises:
a reflector disposed to direct the light to the lens; and
at least one hole disposed to accept at least one electrically conducting pin.

12. The LED insert module as set forth in claim 11, further comprising:
at least one electrically conducting pin disposed in the at least one hole; and
insulation disposed to electrically isolate the at least one pin from the carrier.

13. The LED insert module as set forth in claim 12, wherein:
the at least one LED die comprises at least one anode terminal and at least one cathode terminal;
one of an anode terminal and a cathode terminal is electrically connected to the carrier.

14. The LED insert module as set forth in claim 13, further comprising a plurality of wire bonds that electrically connect a plurality of pins to a plurality of the other of the anode terminals and the cathode terminals.

15. The LED insert module as set forth in claim 12, wherein the at least one LED die comprises at least one anode terminal and at least one cathode terminal, the LED insert module further comprising:
a first plurality of wire bonds that electrically connect a plurality of one of anode terminals and cathode terminals to the carrier; and
a second plurality of wire bonds that electrically connect a plurality of the other of the anode terminals and the cathode terminals.

16. The LED insert module as set forth in claim 12, further comprising a plurality of wire bonds and wherein:
the number of holes is two;
the number of conducting pins is two;
the at least one LED die comprises the at least two LED dies, each LED die having an anode terminal and a cathode terminal; and
the plurality of wire bonds connect the two LED dies in one of a series or parallel electrical connection with the two conducting pins, whereby one of the conducting pins is configured as a cathode of the LED insert module and the other of the conducting pins is configured as an anode of the LED insert module.

17. An LED assembly comprising:
at least one LED insert module, the at least one LED insert module comprising:
a carrier formed of electrically conductive material;
at least one LED die secured to the carrier, the at least one LED die being configured to emit light;
a lens secured to the carrier, the lens comprising a plurality of layers disposed to direct the light to an illumination area; and
a heat sink configured to accept the at least one LED insert module and to dissipate heat generated within the at least one LED insert module.

18. The LED assembly as set forth in claim 17, wherein the plurality of layers are doped with particles of phosphorescent material configured to absorb radiation and to emit light at a wavelength according to the phosphorescent material.

19. The illumination assembly as set forth in claim 18, wherein the particles of phosphorescent material in the plurality of layers are configured to receive light from the at least one LED die.

20. The illumination assembly as set forth in claim 19, wherein the particles of phosphorescent material in one of the plurality of layers are further configured to receive light from phosphorescent material in the plurality of layers.

21. An LED insert module, comprising:
a carrier formed of electrically conductive material, and comprising a proximal end, a distal end, and a longitudinal axis extending within a center of the carrier between the proximal end and the distal end;
at least one LED die secured to the carrier, the at least one LED die being configured to emit light;
a lens secured to the carrier near the distal end of the carrier, the lens comprising a plurality of layers disposed to direct the light distally toward an illumination area;
an insulating sleeve extending substantially parallel to the longitudinal axis of the carrier and extending within the carrier from the proximal end of the carrier to the distal end of carrier; and
a conductive pin disposed within the insulating sleeve.

22. The LED assembly as set forth in claim 21, wherein the plurality of layers are doped with particles of phosphorescent material configured to absorb radiation and to emit light at a wavelength according to the phosphorescent material.

23. The illumination assembly as set forth in claim 21, wherein an anode and a cathode of the LED die are coupled to the carrier and the pin.

24. The LED assembly as set forth in claim 21, wherein the insulating sleeve comprises a longitudinal axis that is parallel to but that does not overlap the longitudinal axis of the carrier, whereby the longitudinal axis of the insulating sleeve is not concentric with, and is off-axis with, the longitudinal axis of the carrier.
